(19) United States
(12) Patent Application Publication
(10) Pub. No.: US 2024/0081020 A1
(43) Pub. Date: Mar. 7, 2024

(54) LIQUID COOLING APPARATUS

(71) Applicants: Inventec (Pudong) Technology Corporation, Shanghai (CN); INVENTEC CORPORATION, Taipei (TW)

(72) Inventors: Xuefeng Chen, Shanghai (CN); Pin-Yi XIANG, Shanghai (CN); Ke Sun, Shanghai (CN)

(21) Appl. No.: 17/946,135

(22) Filed: Sep. 16, 2022

(30) Foreign Application Priority Data
Sep. 6, 2022 (CN) 202211085250.0

(51) Int. Cl. H05K 7/20

(52) U.S. Cl. CPC H05K 7/20263; H05K 7/20136; H05K 7/20236; H05K 7/20272; H05K 7/20763

(57) ABSTRACT

A liquid cooling apparatus is configured to store a first cooling liquid and cool at least one server. The liquid cooling apparatus includes a shell, an immersion tank, a liquid-cooled heat exchanger and a plate heat exchanger. The shell has a device storage space. The immersion tank is located in the device storage space for accommodating the server. The liquid-cooled heat exchanger and the plate heat exchanger are located in the device storage space. The plate heat exchanger has a first channel and a second channel that are not connected. The first channel and the immersion tank together form a first circulation flow channel for accommodating the first cooling liquid, and the second channel and the liquid-cooled heat exchanger together form a second circulating flow channel for accommodating a second cooling liquid. The first cooling liquid and the second cooling liquid exchange heat in the plate heat exchanger.

### CROSS-REFERENCE TO RELATED APPLICATIONS

This non-provisional application claims priority under 35 U.S.C. § 119(a) on Patent Application No(s). 202211085250.0 filed in China, on Sep. 6, 2022, the entire contents of which are hereby incorporated by reference.

### BACKGROUND OF THE INVENTION

### Technical Field of the Invention

The invention relates to a liquid cooling apparatus, more particularly to an integrated immersion liquid cooling apparatus.

### Description of the Related Art

With the rapid development of electronic communication technology, electronic components and chips are developed towards high integration, high computation speed and miniaturization, and the computation speed and performance of servers have been greatly improved. On the other hand, the density of heat transfer on surfaces of each component rapidly increases, so heat generated thereby also increases massively. Therefore, the problem of heat dissipation needs to be solved urgently. Conventionally, the methods of heat dissipation are mainly divided into two types, which are air cooling type and liquid cooling type. The air cooling type is to dissipate heat in an indirect contact manner, which is noisy and cannot meet the heat dissipation requirements under the circumstance where a larger amount of heat is generated in a server since the thermal conductivity of air is much lower than that of cooling liquid. Therefore, for servers with high integration and high heat generation rate, the immersion liquid cooling method with higher cooling efficiency can be adopted to dissipate heat. The method of the immersion liquid cooling is to immerse a server into a liquid tank accommodating cooling liquid, and distribute the cooling liquid to each liquid tank via a cooling distribution unit (CDU). The cooling liquid is in direct contact with each heating component in the servers and takes away heat generated by the heating component. After the heated cooling liquid exchanges heat with cooling water in an external heat exchanger, the cooled cooling liquid returns to the liquid tank via the cooling distribution unit to absorb heat, thus forming a circulation.

However, the conventional liquid cooling system includes several liquid tanks, and the cooling liquid must be distributed via the cooling distribution unit, such that the liquid cooling system is large in size and undesirable in heat dissipation. Therefore, how to further reduce the size of liquid cooling system and improve heat dissipation efficiency has become an important topic in the field.

### SUMMARY OF THE INVENTION

The invention provides a liquid cooling apparatus, whose immersion tank and heat exchanger are integrated with each other, so a cooling distribution unit for distributing cooling liquid is no longer required.

One embodiment of the invention provides a liquid cooling apparatus configured to store a first cooling liquid and cool at least one server via the first cooling liquid. The liquid cooling apparatus includes a shell, an immersion tank, a liquid-cooled heat exchanger, and a plate heat exchanger. The shell has a device storage space. The immersion tank is located in the device storage space. The immersion tank is configured for accommodating the at least one server. The liquid-cooled heat exchanger is located in the device storage space. The plate heat exchanger is located in the device storage space. The plate heat exchanger has a first channel and a second channel that are not connected to each other. The first channel is connected to the immersion tank, and the first channel and the immersion tank together form a first circulating flow channel. The first circulating flow channel is configured for accommodating the first cooling liquid. The second channel is connected to the liquid-cooled heat exchanger, and the second channel and the liquid-cooled heat exchanger together form a second circulating flow channel. The second circulating flow channel is configured for accommodating a second cooling liquid. The first cooling liquid and the second cooling liquid exchange heat in the plate heat exchanger.

Another embodiment of the invention provides a liquid cooling apparatus configured to store a cooling liquid and cool at least one server via the cooling liquid. The liquid cooling apparatus includes a shell, an immersion tank, and a liquid-cooled heat exchanger. The shell has a device storage space. The immersion tank is located in the device storage space. The immersion tank is configured for accommodating the at least one server. The liquid-cooled heat exchanger is located in the device storage space. The liquid-cooled heat exchanger is connected to the immersion tank, and the liquid-cooled heat exchanger and the immersion tank together form a circulating flow channel. The circulating flow channel is configured for accommodating the cooling liquid.

According to the liquid cooling apparatus as described above, since the immersion tank and the heat exchanger together form the circulating flow channel for heat exchange, the immersion tank and the heat exchanger can be integrated with each other without any external component attached thereto, and a cooling distribution unit for distributing cooling liquid is no longer required, either.

### BRIEF DESCRIPTION OF THE DRAWINGS

The invention will become more fully understood from the detailed description given hereinbelow and the accompanying drawings which are given by way of illustration only and thus are not limitative of the invention and wherein:

FIG. 1 is a front perspective view of a liquid cooling apparatus according to the invention;

FIG. 2 is a rear perspective view of the liquid cooling apparatus according to the invention;

FIG. 3 is a cross-sectional view of the liquid cooling apparatus in accordance with the first embodiment of the invention;

FIG. 4 is a cross-sectional view of a plate heat exchanger in FIG. 3; and

FIG. 5 is a cross-sectional view of a liquid cooling apparatus in accordance with the second embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

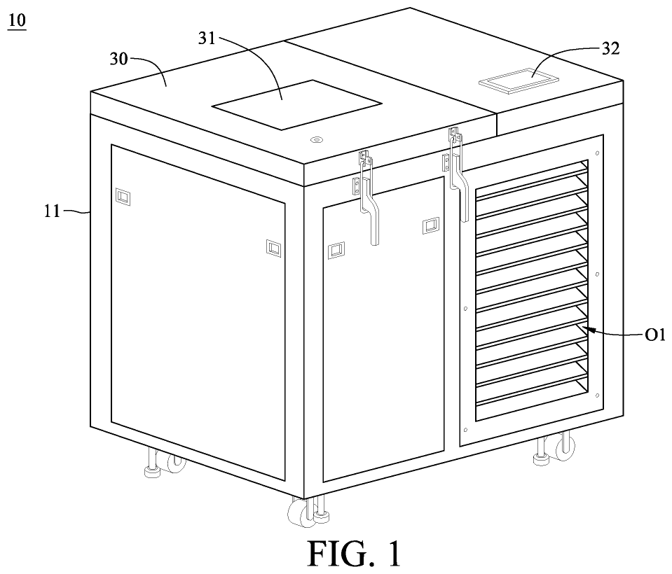

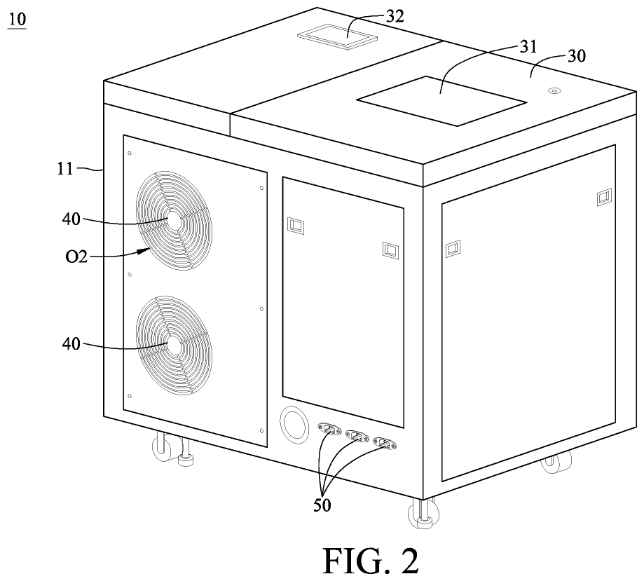

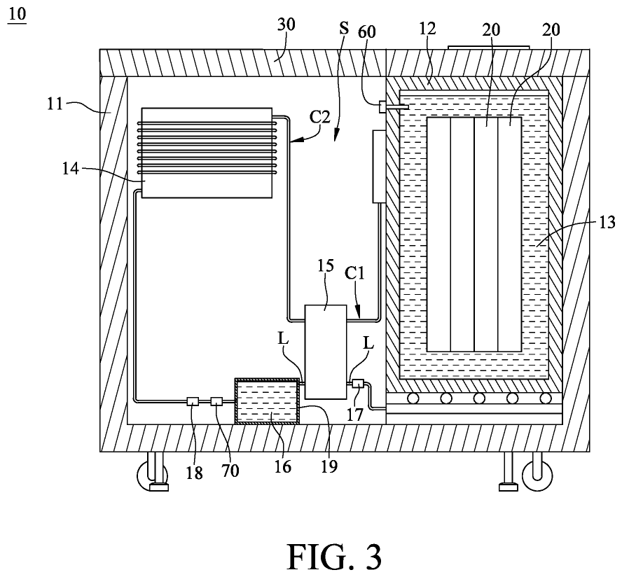

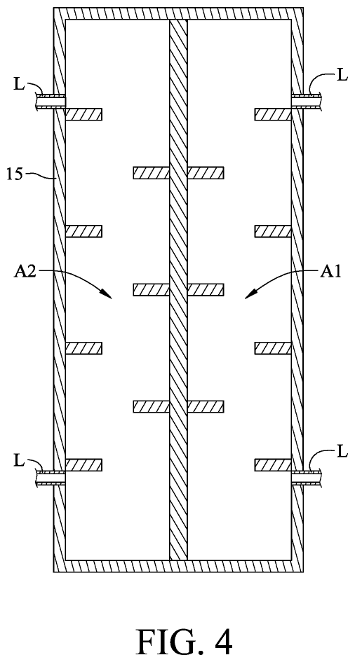

Please referring to FIG. 1 to FIG. 4, which FIG. 1 is a front perspective view of a liquid cooling apparatus according to the invention and FIG. 2 is a rear perspective view of the liquid cooling apparatus according to the invention, and FIG. 3 is a cross-sectional view of the liquid cooling apparatus in accordance with the first embodiment of the invention, and FIG. 4 is a cross-sectional view of a plate heat exchanger in FIG. 3.

In this embodiment, a liquid cooling apparatus 10 is provided. The liquid cooling apparatus 10 includes a shell 11, an immersion tank 12, a liquid-cooled heat exchanger 14, a plate heat exchanger 15, a first pump 17, a second pump 18 and a liquid storage tank 19. The shell 11 has a device storage space S. The immersion tank 12, the liquid-cooled heat exchanger 14 and the plate heat exchanger 15 are disposed in the device storage space S. The immersion tank 12 accommodates a plurality of servers 20 and a first cooling liquid 13. The first cooling liquid 13 is, for example, fluorinated liquid. The servers 20 are immersed in the first cooling liquid 13, and the first cooling liquid 13 takes away heat generated by the servers 20 during operation. The liquid-cooled heat exchanger 14 is, for example, a finned tube heat exchanger. The plate heat exchanger 15 has a first channel A1 and a second channel A2 that are not connected to each other. The first channel A1, the immersion tank 12 and the first pump 17 are connected via pipelines L, and the first channel A1, the immersion tank 12, the first pump 17 and the pipelines L together form a first circulating flow channel C1. The first circulating flow channel C1 is configured for accommodating the first cooling liquid 13. The first pump 17 is configured to drive the first cooling liquid 13 to circulate in the first circulating flow channel C1. The second channel A2, the liquid-cooled heat exchanger 14, the second pump 18 and the liquid storage tank 19 are connected via pipelines L, and the second channel A2, the liquid-cooled heat exchanger 14, the second pump 18, the liquid storage tank 19 and the pipelines L together form a second circulating flow channel C2. The second circulating flow channel C2 is configured for accommodating a second cooling liquid 16. The second cooling liquid 16 is, for example, water. The second pump 18 is configured to drive the second cooling liquid 16 to circulate in the second circulating flow channel C2. The liquid storage tank 19 stores the second cooling liquid 16 which had been cooled by the liquid-cooled heat exchanger 14. The first cooling liquid 13 and the second cooling liquid 16 exchange heat in the first channel A1 and the second channel A2 of the plate heat exchanger 15. Accordingly, during operation, the first cooling liquid 13 takes away heat generated by the servers 20, and the first cooling liquid 13 is driven by the first pump 17 to circulate in the first circulating flow channel C1 constituted by the first channel A1 in the plate heat exchanger 15, the immersion tank 12 and the first pump 17 connected by the pipelines L. In addition, the second cooling liquid 16 is driven by the second pump 18 to circulate in the second circulating flow channel C2 constituted by the second channel A2, which is not connected to the first channel A1 in the plate heat exchanger 15, the liquid-cooled heat exchanger 14, the second pump 18 and the liquid storage tank 19 connected by the pipelines L. The first cooling liquid 13 and the second cooling liquid 16 exchange heat in the first channel A1 and the second channel A2 of the plate heat exchanger 15.

In this embodiment, the quantity of the servers 20 is plural, but the invention is not limited thereto. In other embodiments, the quantity of the server may be one.

In this embodiment, since the immersion tank 12 for accommodating and cooling the servers 20 and the liquid-cooled heat exchanger 14 for cooling the interior of the immersion tank 12 are integrated with each other in the same shell, the liquid cooling apparatus 10 can be used independently. That is, the liquid cooling apparatus 10 can work without an additional external cooling distribution unit (CDU) for distributing the first cooling liquid 13 and cooling the first cooling liquid 13 in the liquid cooling apparatus 10.

In this embodiment, the purpose of disposing the plate heat exchanger 15 to separate the first circulating flow channel C1 and the second circulating flow channel C2 which are independent and disconnected from each other is that if the space of the internal flow channel of the liquid-cooled heat exchanger 14 is relatively large, the first cooling liquid 13, which is relatively costly, only flows in the first circulating flow channel C1 but not in the second circulating flow channel C2 or the liquid-cooled heat exchanger 14 of the second circulating flow channel C2 since the first circulating flow channel C1 and the second circulating flow channel C2 are separated by the plate heat exchanger 15. Since the first cooling liquid 13 does not flow through the internal flow channel of the liquid-cooled heat exchanger 14, the first cooling liquid 13 only flows through a small area and space, and thus, the amount of the first cooling liquid 13 can be reduced, thereby reducing the operation costs of the liquid cooling apparatus 10.

In this embodiment, the first channel A1 and the second channel A2 are tortuous channels, but the invention is not limited thereto. In other embodiments, the first channel A1 and the second channel A2 may be straight channels.

The liquid cooling apparatus 10 further includes a cover 30. The cover 30 and the shell 11 together surround the device storage space S. The cover 30 has a transparent window 31, such as a glass window. The device storage space S is visible from outside through the transparent window 31, so that an operator can monitor the internal condition of the liquid cooling apparatus 10 via the transparent window 31.

The liquid cooling apparatus 10 further includes a control panel 32 disposed on the cover 30. The control panel 32 is configured for monitoring various current states of the liquid cooling apparatus 10, such as, liquid level state, flow state, and temperature state.

The liquid cooling apparatus 10 further includes two fans 40. The shell 11 has a first vent O1 and a second vent O2 at opposite sides thereof, and the two fans 40 are located at one of the vents O1 and O2. When the two fans 40 operates in a forward direction, the fans 40 guide an airflow to flow through the liquid-cooled heat exchanger 14 so as to dissipate heat. When the two fans 40 operates in a direction opposite to the forward direction, the fans 40 suck air along with the dust on the liquid-cooled heat exchanger 14 out of the shell 11.

In this embodiment, the quantity of the fans 40 is two, but the invention is not limited thereto. In other embodiments, the quantity of the fans may be one or more than two.

The liquid cooling apparatus 10 further includes a plurality of power supply interfaces 50 disposed on one side of the shell 11 and electrically connected to the servers 20, the control panel 32, the two fans 40, the first pump 17 and the second pump 18. The power supply interfaces 50 are configured to transmit the power required for operation, and provide redundancy protection for the servers 20.

The liquid cooling apparatus 10 further includes a liquid level sensor 60 disposed outside the immersion tank 12 in the device storage space S. The liquid level sensor 60 is connected to the immersion tank 12 via a pipeline to sense the liquid level of the first cooling liquid 13, and the liquid level sensor 60 is electrically connected to the control panel 32. The control panel 32 sends an alarm when the liquid level of the first cooling liquid 13 is too high.

The liquid cooling apparatus 10 further includes a flowmeter 70. The flowmeter 70 is connected to the second circulating flow channel C2, and the flowmeter 70 is disposed between the second pump 18 and the liquid storage tank 19. The flowmeter 70 is configured to monitor the rate of flow of the second cooling liquid 16 and is electrically connected to the control panel 32.

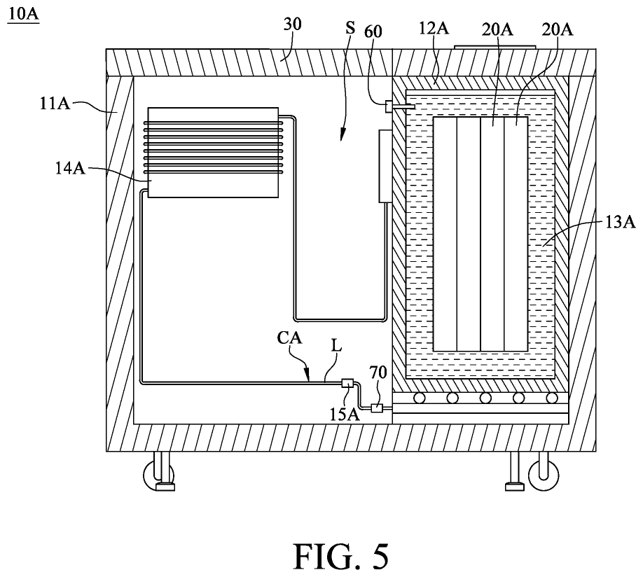

Please referring to FIG. 5, which is a cross-sectional view of a liquid cooling apparatus in accordance with the second embodiment of the invention.

In this embodiment, a liquid cooling apparatus 10A is provided. The liquid cooling apparatus 10A includes a shell 11A, an immersion tank 12A, a liquid-cooled heat exchanger 14A and a pump 15A. The shell 11A has a device storage space S. The immersion tank 12A and the liquid-cooled heat exchanger 14A are disposed in the device storage space S. The immersion tank 12 accommodates a plurality of servers 20A and a cooling liquid 13A. The cooling liquid 13A is, for example, fluorinated liquid. The servers 20A are immersed in the cooling liquid 13A, and the cooling liquid 13A takes away the heat generated by the servers 20A during operation. The liquid-cooled heat exchanger 14A is, for example, a finned tube heat exchanger. The immersion tank 12A, the liquid-cooled heat exchanger 14A and the pump 15A are connected via pipelines L, and the immersion tank 12A, the liquid-cooled heat exchanger 14A, the pump 15A and pipelines L together form a circulating flow channel CA. The circulating flow channel CA is configured for accommodating the cooling liquid 13A. The pump 15A is configured to drive the cooling liquid 13A to circulate in the circulating flow channel CA. Accordingly, during operation, the cooling liquid 13A takes away heat generated by the servers 20A, and the cooling liquid 13A is driven by the pump 15A to circulate in the circulating flow channel CA constituted by the immersion tank 12A, the liquid-cooled heat exchanger 14A and the pump 15A connected by the pipelines L.

In this embodiment, the quantity of the servers 20A is plural, but the invention is not limited thereto. In other embodiments, the quantity of the server may be one.

In this embodiment, since the immersion tank 12A for accommodating and cooling the servers 20A and the liquid-cooled heat exchanger 14A for cooling the interior of the immersion tank 12A are integrated with each other in the same shell, the liquid cooling apparatus 10A can be used independently. That is, the liquid cooling apparatus 10A can work without an additional external cooling distribution unit (CDU) for distributing the cooling liquid 13A and cooling the cooling liquid 13A in the liquid cooling apparatus 10A.

In this embodiment, the purpose of arranging the immersion tank 12A and the liquid-cooled heat exchanger 14A in the same circulating flow channel is that if the space of internal flow channel of the liquid-cooled heat exchanger 14A is relatively small, it has little effect on the amount of the cooling liquid 13A, and there is no need to worry about the cost of the cooling liquid 13A. As such, the configuration of the liquid cooling apparatus 10A can be simplified by omitting a pump and a liquid storage tank. Accordingly, the circulating flow channel CA can be directly formed by the immersion tank 12A, the liquid-cooled heat exchanger 14A and the pump 15A via the pipelines L, thereby simplifying the configuration of the liquid cooling apparatus.

The liquid cooling apparatus 10A further includes a cover 30. The cover 30 and the shell 11A together surround the device storage space S. The cover 30 has a transparent window 31, such as a glass window. The device storage space S is visible from outside through the transparent window 31, so that an operator can monitor the internal condition of the liquid cooling apparatus 10A via the transparent window 31.

The liquid cooling apparatus 10A further includes a control panel 32 disposed on the cover 30. The control panel 32 is configured for monitoring various current states of the liquid cooling apparatus 10A, such as liquid level state, flow state and temperature state.

The liquid cooling apparatus 10A further includes two fans 40. The shell 11A has a first vent O1 and a second vent O2 at opposite sides thereof, and the two fans 40 are located at one of the vents O1 and O2. When the two fans 40 operate in a forward direction, the two fans 40 guide an airflow to flow through the liquid-cooled heat exchanger 14A so as to dissipate heat. When the two fans 40 operate in a direction opposite to the forward direction, the two fans 40 suck air along with the dust on the liquid-cooled heat exchanger 14 out of the shell 11A.

In this embodiment, the quantity of the fans 40 is two, but the invention is not limited thereto. In other embodiments, the quantity of the fans may be one or more than two.

The liquid cooling apparatus 10A further includes a plurality of power supply interfaces 50 disposed on one side of the shell 11A and electrically connected to the servers 20A, the control panel 32, the two fans 40 and the pump 15A. The power supply interfaces 50 are configured to transmit the power required for operation, and provide redundancy protection for the servers 20A.

The liquid cooling apparatus 10A further includes a liquid level sensor 60 disposed outside the immersion tank 12A in the device storage space S. The liquid level sensor 60 is connected to the immersion tank 12A via a pipeline to sense the liquid level of the cooling liquid 13A, and the liquid level sensor 60 is electrically connected to the control panel 32. The control panel 32 sends an alarm when the liquid level of the cooling liquid 13A is too high.

The liquid cooling apparatus 10 further includes a flowmeter 70. The flowmeter 70 is connected to the circulating flow channel CA, and the flowmeter 70 is disposed between the pump 15A and the immersion tank 12A. The flowmeter 70 is configured to monitor the rate of flow of the cooling liquid 13A and is electrically connected to the control panel 32.

According to the liquid cooling apparatus as described above, since the immersion tank and the heat exchanger together form the circulating flow channel in which the cooling liquid can be driven by the pump to circulate for heat exchange, and the fans take the heat out of the shell, the immersion tank and the heat exchanger can be integrated with each other without any external component attached thereto, and a cooling distribution unit for distributing cooling liquid is no longer required, either.

It will be apparent to those skilled in the art that various modifications and variations can be made to the invention. It is intended that the specification and examples be considered as exemplary embodiments only, with the scope of the invention being indicated by the following claims and their equivalents.

What is claimed is:

1. A liquid cooling apparatus, configured to store a first cooling liquid and cool at least one server via the first cooling liquid, comprising:
a shell, having a device storage space;
an immersion tank, located in the device storage space and configured for accommodating the at least one server;
a liquid-cooled heat exchanger, located in the device storage space; and
a plate heat exchanger, located in the device storage space, wherein the plate heat exchanger has a first channel and a second channel that are not connected to each other, the first channel is connected to the immersion tank, the first channel and the immersion tank together form a first circulating flow channel configured for accommodating the first cooling liquid, the second channel is connected to the liquid-cooled heat exchanger, the second channel and the liquid-cooled heat exchanger together form a second circulating flow channel configured for accommodating a second cooling liquid, and the first cooling liquid and the second cooling liquid exchange heat in the plate heat exchanger.

2. The liquid cooling apparatus according to claim 1, further comprising a first pump, wherein the first pump is connected to the first circulating flow channel, and the first pump is configured to drive the first cooling liquid to circulate in the first circulating flow channel.

3. The liquid cooling apparatus according to claim 1, further comprising a second pump, wherein the second pump is connected to the second circulating flow channel, and the second pump is configured to drive the second cooling liquid to circulate in the second circulating flow channel.

4. The liquid cooling apparatus according to claim 1, further comprising a liquid storage tank, wherein the liquid storage tank is connected to the second circulating flow channel, and the liquid storage tank is configured to store the second cooling liquid.

5. The liquid cooling apparatus according to claim 1, further comprising a cover, wherein the cover and the shell together surround the device storage space, the cover has a transparent window, and the device storage space is visible from outside through the transparent window.

6. The liquid cooling apparatus according to claim 1, further comprising at least one fan, wherein the shell has two vents at opposite sides thereof, the at least one fan is located at one of the vents, and the at least one fan is configured to guide an airflow to flow through the liquid-cooled heat exchanger so as to dissipate heat.

7. A liquid cooling apparatus, configured to store a cooling liquid and cool at least one server via the cooling liquid, comprising:
a shell, having a device storage space;
an immersion tank, located in the device storage space and configured for accommodating the at least one server; and
a liquid-cooled heat exchanger, located in the device storage space, wherein the liquid-cooled heat exchanger is connected to the immersion tank, and the liquid-cooled heat exchanger and the immersion tank together form a circulating flow channel configured for accommodating the cooling liquid.

8. The liquid cooling apparatus according to claim 7, further comprising a pump, wherein the pump is connected to the circulating flow channel, and the pump is configured to drive the cooling liquid to circulate in the circulating flow channel.

9. The liquid cooling apparatus according to claim 7, further comprising a cover, wherein the cover and the shell together surround the device storage space, the cover has a transparent window, and the device storage space is visible from outside through the transparent window.

10. The liquid cooling apparatus according to claim 7, further comprising at least one fan, wherein the shell has two vents at opposite sides thereof, the at least one fan is located at one of the vents, and the at least one fan is configured to guide an airflow to flow through the liquid-cooled heat exchanger so as to dissipate heat.
